(19) United States
(12) Patent Application Publication
(10) Pub. No.: US 2025/0292638 A1
(43) Pub. Date: Sep. 18, 2025

(54) SYSTEM AND METHOD FOR MONITORING POWER OF A VEHICLE

(71) Applicants: HYUNDAI MOTOR COMPANY, Seoul (KR); KIA CORPORATION, Seoul (KR)

(72) Inventors: Ki Seon Ryu, Seoul (KR); Mun Young Jeong, Seoul (KR)

(73) Assignees: HYUNDAI MOTOR COMPANY, Seoul (KR); KIA CORPORATION, Seoul (KR)

(21) Appl. No.: 18/924,492

(22) Filed: Oct. 23, 2024

(30) Foreign Application Priority Data
Mar. 15, 2024 (KR) 10-2024-0036355

(51) Int. Cl. G07C 5/10; G01R 19/25; G01R 31/00; G07C 5/04; G07C 5/08; H01M 10/48

(52) U.S. Cl. CPC G07C 5/10; G01R 19/2513; G01R 31/007; G07C 5/04; G07C 5/0825; H01M 10/48; H01M 2220/20

(57) ABSTRACT

A system and method for monitoring power of a vehicle which may monitor a state of charge of a battery of a vehicle and may notify a customer of a state and a response thereof. The system for monitoring power of a vehicle may include: a processor; and a storage medium in which one or more programs configured to be executable by the processor are recorded. The processor may execute the one or more programs to: store power consumption data for each preset vehicle state; calculate an expected discharge time of a battery of the vehicle based on power consumption data classified by preset electrical equipment and the store power consumption data; and display the power consumption data of the electrical equipment and the expected discharge time of the battery.

### CROSS-REFERENCE TO RELATED APPLICATION(S)

This application claims the benefit of and priority to Korean Patent Application No. 10-2024-0036355, filed on Mar. 15, 2024, the disclosure of which is incorporated herein by reference in its entirety.

### BACKGROUND

### 1. Field

The present disclosure relates to a system and a method for monitoring power of a vehicle.

### 2. Description of Related Art

A dashcam, which has been rapidly spreading in the aftermarket in recent years, is popular among drivers because such a dashcam may provide important evidence to determine fault in the event of an accident.

The dashcam is useful in the event of damage or a collision with a driving vehicle as well as a parked vehicle, but when operating a camera in the parked vehicle, there may be a problem in that a battery of the vehicle may be discharged due to current consumption by the dashcam.

### SUMMARY

An aspect of the present disclosure provides a system and a method for monitoring power of a vehicle which may monitor a state of charge of a battery of a vehicle and may notify a customer of a state and a response thereof.

According to an embodiment of the present disclosure, a system for monitoring power of a vehicle may include: a processor; and a storage medium in which one or more programs configured to be executable by the processor are recorded. The processor may execute the one or more programs to: store power consumption data for each preset vehicle state; calculate an expected discharge time of a battery of the vehicle based on power consumption data classified by preset electrical equipment and the stored power consumption data (e.g., calculate an expected discharge time of a battery of the vehicle by calculating power consumption data classified by preset electrical equipment from the stored power consumption data); and display the power consumption data of the electrical equipment and the expected discharge time of the battery.

A system for monitoring power of a vehicle according to another embodiment may include: a processor; and a storage medium in which one or more programs configured to be executable by the processor are recorded, wherein the one or more programs may be executed by the processor. The processor may execute the one or more programs to: store power consumption data for each preset vehicle state; confirm lack of a charge rate and charge time of a battery of the vehicle based on the stored power consumption data;

calculate a driving pattern of a customer; guide a battery management plan based on the calculated driving pattern of the customer; and suggest entering a battery care mode for the battery.

A method for monitoring power of a vehicle according to an embodiment may be performed on a computing device including a processor, and a storage medium in which one or more programs configured to be executable by the processor is recorded. The method may include: storing power consumption data for each preset vehicle state; calculating an expected discharge time of a battery of the vehicle by calculating power data (e.g., power consumption data) classified by preset electrical equipment from data stored in the storing step; and displaying the power consumption data of the electrical equipment and the expected discharge time of the battery calculated in the calculating step.

A method for monitoring power of a vehicle according to another embodiment may be performed on a computing device including a processor, and a storage medium in which one or more programs configured to be executable by the processor is recorded. The method may include: storing power consumption data for each preset vehicle state; confirming lack of a charge rate and charge time of a battery of the vehicle based on data stored in the storing step; calculating a driving pattern of a customer; guiding a battery management plan based on the driving pattern of the customer calculated in the calculating step; and suggesting entering a battery care mode for the battery.

According to an embodiment of the present disclosure, by maintaining an appropriate battery charge amount and monitoring whether periodic charging is performed, it may be possible to increase battery lifespan by informing customers of the conditions under which the battery's durability may be maintained for a long period of time.

### BRIEF DESCRIPTION OF DRAWINGS

The above and other aspects, features, and advantages of the present disclosure should be more clearly understood from the following detailed description, taken in conjunction with the accompanying drawings, in which:

FIG. 1 is a schematic block diagram of a system for monitoring power of a vehicle according to an embodiment of the present disclosure;

FIG. 2 is an operation flowchart schematically illustrating a method for monitoring power of a vehicle according to an embodiment of the present disclosure;

FIG. 3 is a detailed operation flowchart of a power data calculation operation in the method for monitoring power of a vehicle according to an embodiment of the present disclosure illustrated in FIG. 2;

FIG. 4 is a detailed operation flowchart of an operation of calculating an expected discharge time in the vehicle power monitoring method according to an embodiment of the present disclosure illustrated in FIG. 2;

FIG. 5 is a screen for guiding influence by electronic equipment in a system for monitoring power of a vehicle according to an embodiment of the present disclosure;

FIG. 6 is a schematic block diagram of a system for monitoring power of a vehicle according to another embodiment of the present disclosure;

FIG. 7 is an operation flowchart schematically illustrating a method for monitoring power of a vehicle according to another embodiment of the present disclosure;

FIGS. 8 and 9 are detailed operation flowcharts of a battery care service in a method for monitoring power of a vehicle according to another embodiment of the present disclosure illustrated in FIG. 7;

FIG. 10 is a table illustrating a dark current minimization mode of a battery care service in a method for monitoring power of a vehicle according to another embodiment of the present disclosure illustrated in FIG. 7;

FIG. 11 is a screen for guiding a battery care service in a system for monitoring power of a vehicle according to another embodiment of the present disclosure; and

FIG. 12 is a block diagram of a computing device capable of entirely or partially implementing a system for monitoring power of a vehicle according to an embodiment of the present disclosure.

The drawings described herein are for illustration purposes only and are not intended to limit the scope of the present disclosure in any way.

### DETAILED DESCRIPTION

Hereinafter, specific embodiments of the present disclosure are described with reference to the drawings. The following detailed description is provided to help gain a comprehensive understanding of methods, apparatuses, and/or systems described herein. However, this is only an example, and the present disclosure is not limited thereto.

In describing embodiments of the present disclosure in detail, when it is determined that a detailed description of known technologies associated with the present disclosure may unnecessarily obscure the gist of the present disclosure, the detailed description thereof is omitted. Furthermore, the terms described below are defined in consideration of functions in the present disclosure, and may vary according to the intention or practice of a customer or an operator. Therefore, the definition thereof should be based on the content throughout this specification. The terms used in the description are intended to describe embodiments only, and shall by no means be restrictive. Unless clearly used otherwise, expressions in a singular form include a meaning of a plural form. In the present description, an expression such as “comprising” or “including” and the like are intended to designate a characteristic, a number, a step, an operation, an element, a portion or combinations thereof. Such terms shall not be construed to preclude any presence or possibility of one or more other characteristics, numbers, steps, operations, elements, parts or combinations thereof. When a component, processor, controller, device, element, unit, apparatus, or the like of the present disclosure is described as having a purpose or performing an operation, function, or the like, the component, processor, controller, device, element, unit, apparatus, or the like should be considered herein as being “configured to” meet that purpose or to perform that operation or function.

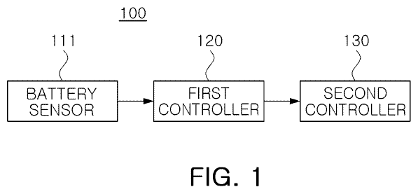

FIG. 1 is a schematic block diagram system for monitoring power of a vehicle according to an embodiment of the present disclosure.

Referring to FIG. 1, a system 100 for monitoring power of a vehicle according to an embodiment of the present disclosure may include a battery sensor 111, a first controller 120, and a second controller 130.

The battery sensor 111 may sense information on power of a battery of a vehicle. Accordingly, power consumption may be stored according to a preset state of a vehicle provided with the battery. In this case, the power consumption may be classified and stored according to a state of the vehicle. For example, the power consumption may be classified according to vehicle states such as driving, stopping, and parking, and may be stored.

The first controller 120 may be a vehicle customer relationship management (VCRM) server or a vehicle terminal configured to analyze data to improve vehicle quality and service.

The first controller 120 may calculate an expected discharge time of a battery of a vehicle by calculating power data classified by preset electrical equipment from data stored by a battery sensor 111. The electrical equipment may be an electrical equipment such as a dashcam in the aftermarket.

The second controller 130 may be an application or a vehicle terminal installed on the customer's mobile phone to check a vehicle status and receive various information.

The second controller 130 may display the calculated power consumption of the electrical equipment and the expected discharge time of the battery to the customer.

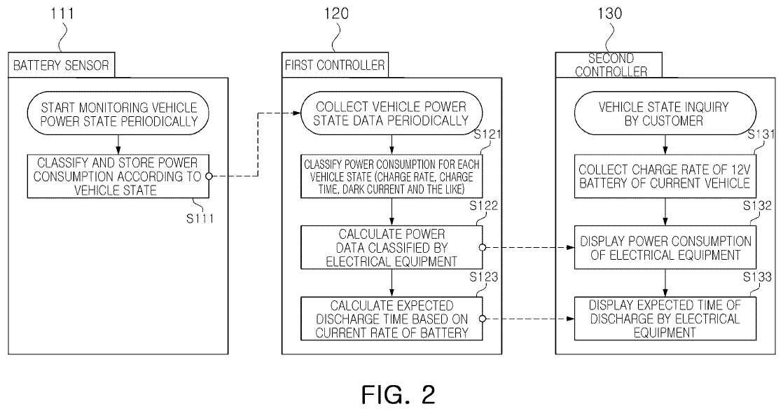

FIG. 2 is an operation flowchart schematically illustrating a method for monitoring power of a vehicle to an embodiment of the present disclosure.

Referring to FIG. 2 along with FIG. 1, in order to periodically monitor a power state of the vehicle, the battery sensor 111 may classify power consumption according to a preset state of a vehicle provided with a battery and store the power consumption (S111).

The first controller 120 may periodically collect and store vehicle power state data from the battery sensor 111, and classify the stored power consumption data for each vehicle state according to preset types (S121). For example, the stored power consumption data for each vehicle state may be classified into a charge rate, a charge time, a dark current of the battery, and the like. The dark current refers to a current flowing when a vehicle engine is turned off, and may denote, for example, a current consumed from the battery due to the power required for an operation of electrical equipment such as a dashcam, and the power required for receiving a signal from a smart key or basic operations such as theft prevention. With an increase in the amount of dark current, the discharge speed of the battery may become faster.

Then, the first controller 120 may calculate power data classified by the electrical equipment (e.g., power consumption data of each electrical equipment) (S122).

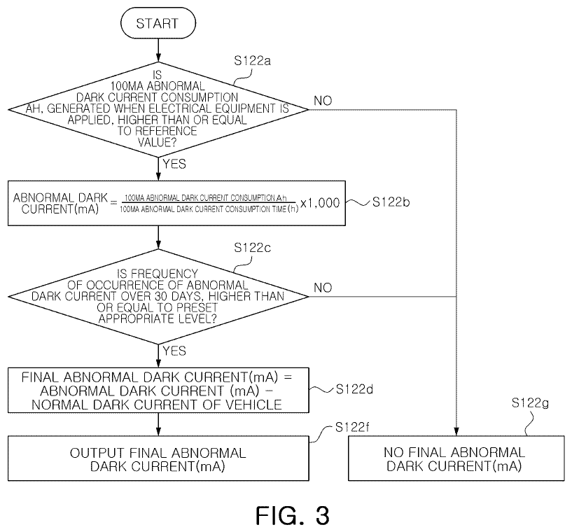

FIG. 3 is a detailed operation flowchart of a power data calculation operation in the method for monitoring power of a vehicle according to an embodiment of the present disclosure illustrated in FIG. 2.

Referring to FIGS. 2 and 3, an operation of calculating power consumption data (S122), the first controller 120 may perform an operation of determining whether an abnormal dark current is generated by the electrical equipment (S122a), an operation of calculating the abnormal dark current according to consumption ampere-hours (ampere per hour, Ah) of the abnormal dark current higher than or equal to a preset reference value and the consumption time of the abnormal dark current (S122b), determining whether the calculated abnormal dark current is higher than or equal to a preset appropriate level (S122c), calculating final abnormal dark current according to a difference between the abnormal dark current and a normal dark current of the vehicle (S122d), and an operation of outputting the calculated final abnormal dark current value or an absence of the final abnormal dark current (S122e and S122f).

More specifically, the first controller 120 may determine whether ampere-hours of the abnormal dark current, for example, 100 mA, generated when the electrical equipment is applied to the vehicle, is higher than or equal to the reference value (S122a), and may calculate the abnormal dark current when the ampere-hours is higher than or equal to the reference value (S122b).

The abnormal dark current may be obtained according to Equation 1 below.

$$ABNORMAL DARK CURRENT ( mA ) = \frac{\begin{matrix}100 mA ABNORMAL DARK \\ CURRENT CONSUMPTION Ah\end{matrix}}{\begin{matrix}100 mA ABNORMAL DARK \\ CURRENT CONCUPTION TIME ( h )\end{matrix}} \times 1 , 000 \qquad Equation 1$$

Then, the first controller 120 may determine whether the frequency of occurrence of abnormal dark current calculated over, for example, 30 days, is higher than or equal to a preset appropriate level (S122c), may calculate, when the frequency is higher than or equal to the preset appropriate level, final abnormal dark current according to a difference between the calculated abnormal dark current and a normal dark current of the vehicle (S122d), and may output the final abnormal dark current (S122e). The first controller 120 may determine that there is no final abnormal dark current when the ampere-hours of the abnormal dark current is less than or equal to the reference value or the calculated frequency of occurrence of abnormal dark current is less than or equal to the appropriate level.

Referring again to FIG. 2, the first controller 120 may calculate power data classified by the electrical equipment (e.g., power consumption data of each electrical equipment) and calculate an expected discharge time of the battery of the vehicle (S123).

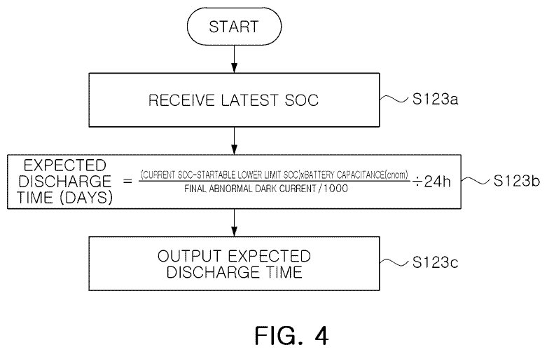

FIG. 4 is a detailed operation flowchart of an operation of calculating an expected discharge time in the vehicle power monitoring method according to an embodiment of the present disclosure illustrated in FIG. 2.

Referring to FIGS. 2 and 4, in an operation of calculating the expected discharge time of the battery (S123), the first controller 120 may perform an operation of receiving a state of charge of the battery (S123a), an operation of calculating the expected discharge time of the battery based on a current state of charge of the battery, a preset lower limit charge state for starting the vehicle, capacitance of the battery, and the final abnormal dark current (S123b), and an operation of outputting the calculated expected discharge time (123c).

The first controller 120 may receive the latest state of charge (SoC) of the battery measured by the battery sensor 111 (S123a), and may calculate the expected discharge time of the battery (S123b).

The first controller 120 may calculate the expected discharge time of the battery according to Equation 2 below.

$$EXPECTED DISCHARGE TIME ( DAYS ) = \frac{\begin{matrix}( {CURRENT}_{SOC} - STARTABLE LOWER \\ {LIMIT}_{SOC} ) \times BATTERY CAPACITANCE ( cnom ) +\end{matrix}}{FINAL ABNORMAL DARK CURRENT / 1000} \div 24 h \qquad Equation 2$$

The first controller 120 may output the expected discharge time calculated by Equation 2 above (S123c).

Referring again to FIG. 2, the second controller 130 may collect a charge rate of the battery of the vehicle according to a vehicle state inquiry of the customer to display the power consumption of the electrical equipment calculated by the first controller 120 and the expected discharge time of the battery to the customer (S131 and S132).

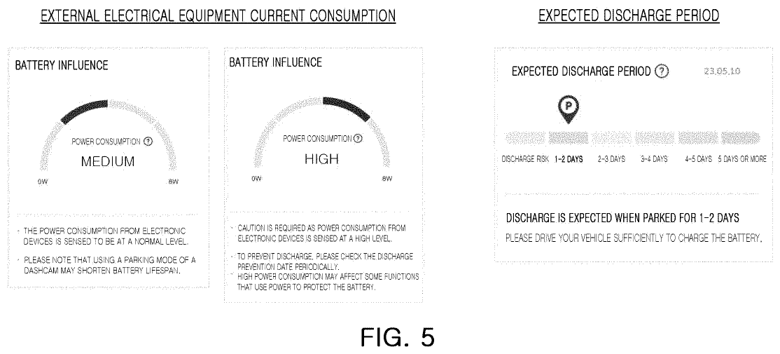

FIG. 5 is a screen for guiding influence by electronic equipment in a system for monitoring power of a vehicle according to an embodiment of the present disclosure.

Referring to FIG. 5, when installing aftermarket electrical equipment (external electrical equipment) in a vehicle, a battery influence and an expected discharge period may be displayed to the customer depending on the power consumption of the corresponding vehicle.

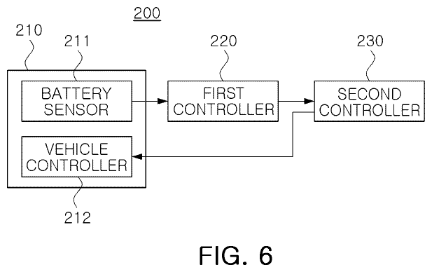

FIG. 6 is a schematic block diagram of a system for monitoring power of a vehicle according to another embodiment of the present disclosure.

Referring to FIG. 6, a system 200 for monitoring power of a vehicle according to another embodiment of the present disclosure may include a battery sensor 211, a vehicle controller 212, a first controller 220, and a second controller 230 of the vehicle.

The battery sensor 211 may sense information on the power of the battery of the vehicle.

The vehicle controller 212 may enter a battery care mode to care for the battery under the control of the second controller 230. The vehicle controller 212 may be, for example, an Electronic Controller (ECU).

The first controller 220 may be a Vehicle Customer Relationship Management (VCRM) server or a vehicle terminal capable of confirming lack of a charge rate and charge time of the battery of the vehicle based on stored data and calculating a driving pattern of the customer.

The second controller 230 may be an application or a vehicle terminal capable of guiding a battery management plan according to the calculated driving pattern of the customer and suggesting entering the battery care mode for the battery, and installed on a mobile phone of the customer to check the vehicle state and receive various information.

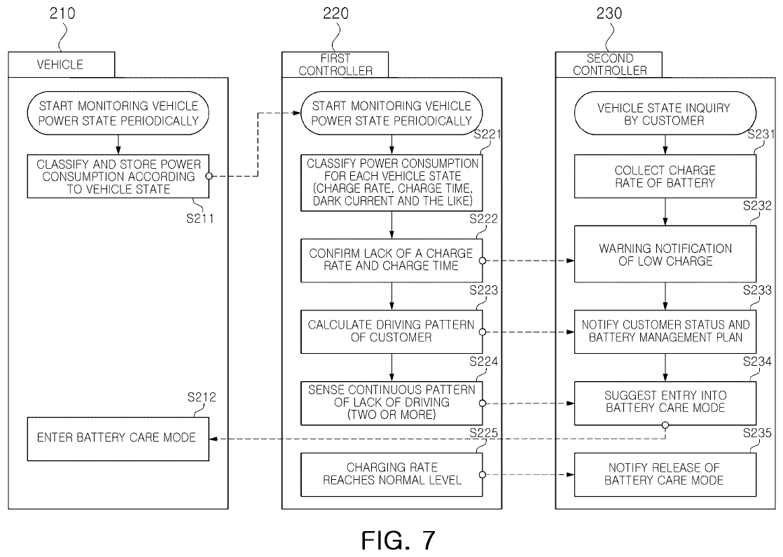

FIG. 7 is an operation flowchart schematically illustrating a method for monitoring power of a vehicle according to another embodiment of the present disclosure.

Referring to FIGS. 6 and 7, in order to periodically monitor a power state of the vehicle, the battery sensor 211 may classify power consumption according to a preset state of the vehicle provided with the battery and store the power consumption (S211).

The first controller 220 may periodically collect and store vehicle power state data from the battery sensor 211, and classify the stored power consumption data for each vehicle state according to preset types (S221). For example, the stored power consumption data for each vehicle state may be classified into a charge rate, a charge time, and a dark current of the battery.

Accordingly, the first controller 220 may confirm the lack of the charge rate and charge time of the battery according to the stored power consumption data for each vehicle state (S222). The first controller 220 may confirm the lack of a charge rate and charge time of the battery based on a state of charge (SoC) of the battery sensed by the battery sensor 211.

The second controller 230 may collect the charging rate of the battery of the vehicle according to the vehicle state inquiry of the customer (S231), and may generate a notification warning of lack of charged power of the battery as the first controller 220 confirms the lack of the charging rate and charge time of the battery (S232).

Next, the first controller 220 may calculate the driving pattern of the customer for a preset period of time (S223). The period of time may be identical to a period of time for confirming the lack of the charge rate and charge time of the battery. Additionally, the first controller 220 may receive average driving patterns of other customers for a preset period of time.

Accordingly, the second controller 230 may notify a customer status and a battery management plan to the customer (S233). Additionally, the second controller 230 may notify the customer status and the battery management plan to the customer by comparing the average driving patterns of other customers, and may control entering a dark current minimization mode in the vehicle controller 212.

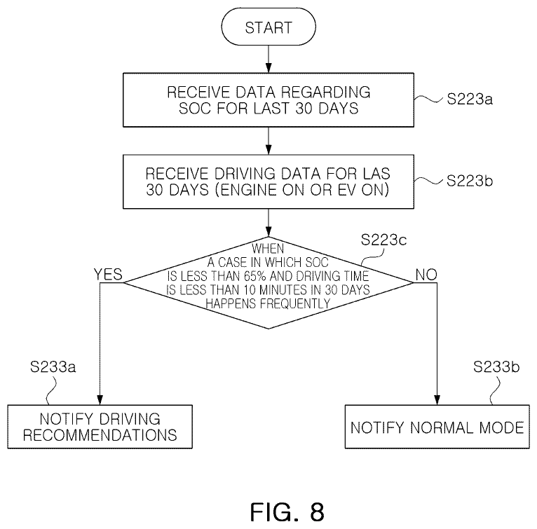

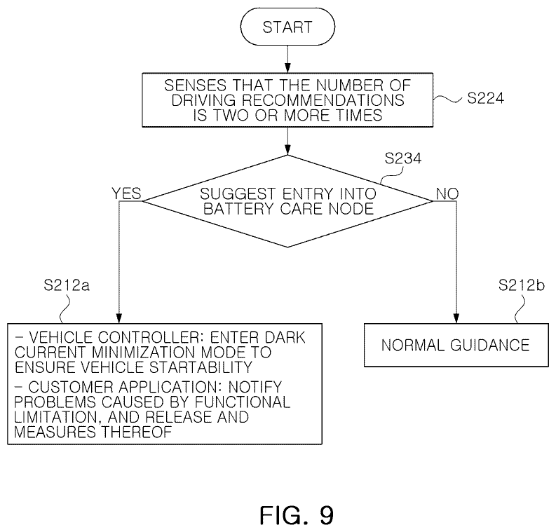

FIGS. 8 and 9 are detailed operation flowcharts of a battery care service in a method for monitoring power of a vehicle according to another embodiment of the present disclosure illustrated in FIG. 7.

Referring to FIGS. 7 and 8, the first controller 220 may receive data regarding the state of charge (SoC) of the battery for a preset period of time (S223a). For example, the preset period of time may be the last 30 days. Then, the first controller 220 may receive driving data for a preset period of time (S223b). Similarly, for example, the preset period of time may be the last 30 days. The driving data may be data when an engine of the vehicle 200 operates, or when an electric motor of an electric vehicle operates, and the data may be received from a sensor or various controllers (not illustrate) of the vehicle 200. The first controller 220 determine whether for the period of time, the number of cases in which the state of charge (SoC) of the battery is less than or equal to a preset standard, and the driving time of the vehicle is less than or equal to a preset standard driving time is higher than or equal to a preset number of times. For example, the standard may be 658, and the standard driving time may be 10 minutes. This may be set in consideration of the time the battery may be charged depending on driving. The number of times may be set in consideration of discharge of the battery, charging during driving, and the like.

The second controller 230 may notify the customer of driving recommendations to prevent battery discharge of the vehicle when the number of cases in which the state of charge (SoC) of the battery is 65% or less and the driving time of the vehicle is 10 minutes or less depending on the determination of the first controller 220 is higher than or equal to a preset number of times (S233a), and notify the customer that the vehicle is normal when the number of cases is less than or equal to the preset number of times (S233b).

Referring to FIGS. 7 and 9, when the first controller 220 senses that the number of driving recommendations of the second controller 230 is higher than or equal to the preset number of times, for example, two or more times (S224), detection results may be transmitted to the second controller 230, and the second controller 230 may suggest entering a battery care mode to the customer (S234). When the customer is permitted to enter the battery care mode, the second controller 230 may control the vehicle controller 212 to enter the dark current minimization mode to ensure vehicle startability, and may notify the customer of problems caused by a functional limitation due to entering the dark current minimization mode through the application, and release and measures thereof (S212a). When the customer is not permitted to enter the battery care mode, a normal mode may be notified to the customer (S212b).

Referring again to FIG. 7, when the charging rate of the battery enters a normal mode (S225), the first controller 220 may transmit to the second controller 230 that the charging rate of the battery is normal, and the second controller 230 may notify the customer of the release of the battery care mode (S235). Then, the second controller 230 may control the vehicle controller 212 to release the battery care mode (not illustrated).

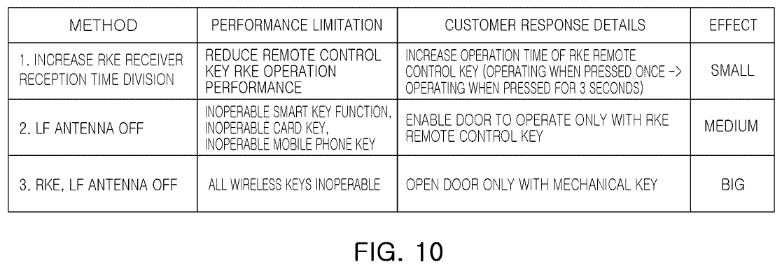

FIG. 10 is a table illustrating a dark current minimization mode of a battery care service in a method for monitoring power of a vehicle according to another embodiment of the present disclosure illustrated in FIG. 7.

First, the dark current of the vehicle is mainly generated by an operation of a customer convenience function (welcome light, remote control, and the like) and an access function (remote control key operation) during parking.

The customer convenience functions include a: function limiting operation depending on the charge rate of the battery, and the access function is an important function for the customer and does not provide an off function because the customer may feel inconvenienced immediately. However, for customers who do not use vehicles thereof frequently and are at risk of battery performance degradation and discharge, an option battery performance even at the expense of performance degradation in some functions may be useful.

Accordingly, in the present disclosure, for customers who drive the vehicle infrequently, a function in which the application may allow the customers to choose degradation of some of the functions of the vehicle and obtain consent thereof and the pertinent content is then notified through the application may be provided.

There is a limit to the customer convenience and dark current described above due to a trade-off relationship, but the present disclosure may respond to the trade-off limitation by providing selection and guidance to customers through a mobile phone app.

Referring to FIG. 10, the above-described battery care service may include \textcircled{1} increasing a reception time division of a Remote Keyless Entry (RKE) receiver for the vehicle, \textcircled{2} turning off a low frequency (LF) antenna for a smart key system, and \textcircled{3} turning off an antenna and a low-frequency antenna of the Remote Keyless Entry (RKE) receiver for the vehicle.

\textcircled{1} When increasing the reception time division of the Remote Keyless Entry (RKE) receiver for the vehicle, the operating performance of the Remote Keyless Entry (RKE) receiver for the vehicle of a remote control key may be deteriorated, which may increase the operating time of the remote control key of the customer, for example, changing the operation time from operating when pressed once to operating when pressed for 3 seconds, so that battery power consumption may be reduced, and an effect of the battery care service may be considered ‘small.’

Additionally, \textcircled{2} when turning off the low-frequency antenna for the smart key system, a smart key of the vehicle, a card key, and a cell phone key may be inoperable, which change an operation manner to enable a door to operate only with the remote control key of the customer, so that an effect of the battery care service may be considered ‘medium.’

Lastly, \textcircled{3} when turning off the antenna and the low-frequency antenna of the Remote Keyless Entry (RKE) receiver for the vehicle, all wireless keys in the vehicle may become inoperable, and an effect of the battery care service may be considered ‘significant’ by changing the operation manner to enable the door to be opened only with a mechanical key of the vehicle.

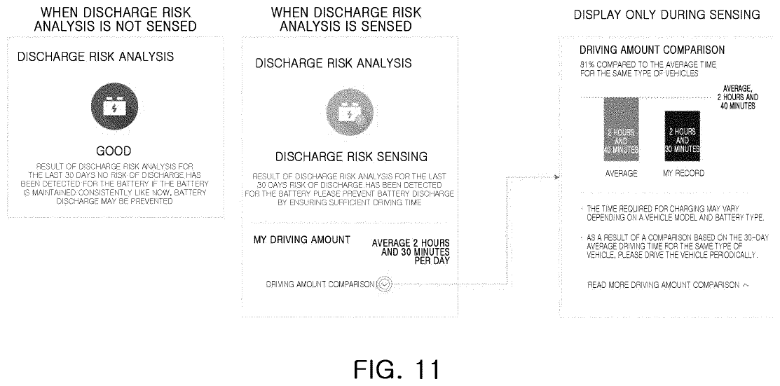

FIG. 11 is a screen for guiding a battery care service in a system for monitoring power of a vehicle according to another embodiment of the present disclosure.

Referring to FIG. 11, in a system for monitoring power of a vehicle according to another embodiment of the present disclosure, as described above, when normal guidance is provided, a discharge risk analysis may be displayed as ‘good’ on a mobile phone application or a vehicle terminal of the customer, and when guiding a vehicle operation according to the risk of battery discharge, the discharge risk analysis may be displayed as ‘discharge risk detection’ on the mobile phone application or the vehicle terminal of the customer to guide the vehicle operation. Additionally, the average driving patterns of other customers may be compared to provide the customer with a customer status and a battery management plan.

As described above, according to the present disclosure, an appropriate battery charge may be maintained and periodic charging may be monitored, so that the customer may be provided with the conditions under which the durability of the battery may be maintained for a long period of time, thereby increasing the lifespan of the battery.

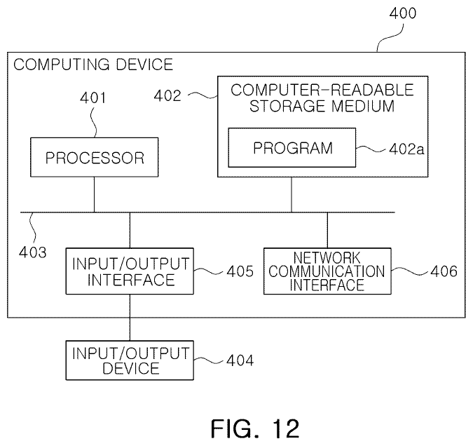

FIG. 12 is a block diagram of a computing device capable of entirely or partially implementing a system for monitoring power of a vehicle according to an embodiment of the present disclosure, and may be a system 100 for monitoring power of a vehicle illustrated in FIGS. 1 and 6.

As illustrated in FIG. 12, a computing device 400 includes at least one processor 401, a computer-readable storage medium 402, and a communication bus 403.

The processor 401 may enable the computing device 400 to operate according to the embodiments described above. For example, the processor 401 may execute one or more programs stored in the computer-readable storage medium 402. The one or more programs may include one or more computer executable instructions, and the computer-executable instructions, when executed by the processor 401, may be configured to cause the computing device 400 to perform operations according to embodiments.

The computer-readable storage medium 402 is configured to store computer-executable instructions or a program code, program data, and/or other suitable form of information. A program 402a stored in the computer-readable storage medium 402 includes a set of instructions executable by the processor 401. In an embodiment, the computer-readable storage medium 402 may be a memory (a volatile memory such as a random access memory, a non-volatile memory, or an appropriate combination thereof), one or more magnetic disk storage devices, optical disk storage devices, flash memory devices, another type of storage medium accessed by other computing device 400 and capable of storing desired information, or an appropriate combination thereof.

The communication bus 403 may include a processor 401 and a computer-readable storage medium 402 to interconnect various other components of the computing device 400.

The computing device 400 may also include one or more input/output interfaces 405 that provide an interface for one or more input/output devices 404 and one or more network communication interfaces 406. The input/output interface 405 and the network communication interface 406 are connected to the communication bus 403. The input/output device 404 may be connected to other components of the computing device 400 through the input/output interface 405. The exemplary input/output device 404 may include input devices such as a pointing device (such as a mouse or a trackpad), a keyboard, a touch input device (such as a touchpad or a touchscreen), a voice or sound input device, or various types of sensor devices and/or imaging devices, and/or output devices such as a display device, a printer, a speaker and/or a network card. The exemplary input/output device 404 may be included in the computing device 400 as a component included in the computing device 400, and may be a separate device that is distinct from the computing device 400 and may be connected to the computing device 400.

Embodiments of the present disclosure may include a program for performing the methods described herein on a computer, and a computer-readable recording medium including the program. The computer-readable recording medium may include program instructions, local data files and local data structures, alone or in combination. The medium may be specially designed and constructed for the present disclosure, or may also be commonly available in the computer software field. Examples of the computer-readable recording medium include magnetic media such as a hard disk, a floppy disk and a magnetic tape, optical recording media such as CD-ROM and DVD, and hardware devices specifically configured to store and execute program instructions, such as ROM, RAM, and a flash memory. Examples of the program may include not only a machine language code such as that generated by a compiler, but also a high-level language code executable by a computer using an interpreter or the like.

While embodiments of the preset disclosure have been described above in detail, it may be understood by those having ordinary skill in the art that the example embodiments may be variously modified without departing from the scope of the present disclosure. Therefore, the scope of the present disclosure is defined not by the described embodiments but by the appended claims, and encompasses equivalents that fall within the scope of the appended claims.

What is claimed is:

1. A system for monitoring power of a vehicle, comprising:
a processor; and
a storage medium in which one or more programs configured to be executable by the processor are recorded,
wherein the processor is configured to execute the one or more programs to:
store power consumption data for each preset vehicle state;
calculate an expected discharge time of a battery of the vehicle based on power consumption data classified by preset electrical equipment and the stored power consumption data; and
display the power consumption data of the electrical equipment and the expected discharge time of the battery.

2. The system according to claim 1, wherein the power consumption data is acquired by a battery sensor of the vehicle and classified based on the vehicle state.

3. The system according to claim 1, wherein when the processor executes the one or more programs to calculate the expected discharge time, the processor is configured to execute the one or more programs to:
classify the stored power consumption data for each preset vehicle state based on preset types;
calculate the power consumption data of the electrical equipment based on the classified power consumption data; and
calculate the expected discharge time of the battery based on a current charge rate of the battery.

4. The system according to claim 3, wherein when the processor executes the one or more programs to calculate the power consumption data, the processor is configured to execute the one or more programs to:
determine whether an abnormal dark current is generated by the electrical equipment;
calculate the abnormal dark current based on consumption ampere-hours (ampere per hour, Ah) of the abnormal dark current higher than or equal to a preset reference value and consumption time of the abnormal dark current;
determine whether the calculated abnormal dark current is higher than or equal to a preset appropriate level;
calculate a final abnormal dark current based on a difference between the abnormal dark current and a normal dark current of the vehicle; and
output a value of the calculated final abnormal dark current or an absence of the final abnormal dark current, and
wherein when the processor executes the one or more programs to calculate the expected discharge time of the battery, the processor is configured to execute the one or more programs to:
receive a state of charge (SOC) of the battery;
calculate the expected discharge time of the battery based on a current SOC of the battery, a preset lower limit charge state for starting the vehicle, capacitance of the battery, and the final abnormal dark current; and
output the calculated expected discharge time.

5. The system according to claim 3, wherein when the processor executes the one or more programs to display the power consumption data of the electrical equipment and the expected discharge time of the battery, the processor is configured to execute the one or more programs to:
collect a charge rate of the battery of the vehicle;
display the power consumption data of the electrical equipment based on the calculated power consumption data; and
display the expected discharge time of the battery by the electrical equipment.

6. A system for monitoring power of a vehicle, the system comprising:
a processor; and
a storage medium in which one or more programs configured to be executable by the processor are recorded,
wherein the processor is configured to execute the one or more programs to:
store power consumption data for each preset vehicle state;
confirm lack of a charge rate and charge time of a battery of the vehicle based on the stored power consumption data;
calculate a driving pattern of a customer;
guide a battery management plan based on the calculated driving pattern of the customer; and
suggest entering a battery care mode for the battery.

7. The system according to claim 6, wherein the processor is configured to execute the one or more programs to:
when the processor executes the one or more programs to store the power consumption data for each preset vehicle state, classify and store power consumption data acquired by a battery sensor of the vehicle based on the vehicle state; and
enter the battery care mode according to the suggestion of entering the battery care more for the battery.

8. The system according to claim 7, wherein when the processor executes the one or more programs to calculate the driving pattern of the customer, the processor is configured to:
classify the stored power consumption data for each preset vehicle state based on preset types;
confirm lack of a charge rate and charge time of the battery based on the classified power consumption data;
calculate an average driving pattern of the customer for a preset period of time;
sense a continuous pattern of lack of driving of the vehicle; and
recognize a charge rate normal mode entry for the battery.

9. The system according to claim 8, wherein when the processor executes the one or more programs to suggest entering the battery care mode for the battery, the processor is configured to execute the one or more programs to:
collect a charge rate of the battery of the vehicle;
notify a low-charge warning based on confirmation of the lack of the charge rate and charge time of the battery;
guide a customer status and a battery management plan based on the calculated average driving pattern;
suggest entering the battery care mode; and
release the battery care mode when the charge rate of the battery enters a normal mode,
wherein when the processor executes the one or more programs to calculate the driving pattern, the processor is configured to execute the one or more programs to:
receive charge state data of the battery for the period of time;
receive driving data of the vehicle for the period of time; and
determine whether for the period of time, the number of cases in which the state of charge of the battery is less than or equal to a preset standard and driving time of the vehicle is less than or equal to a preset standard driving time is higher than or equal to a preset number of times, and
wherein when the processor executes the one or more programs to guide the battery management plan, the processor is configured to execute the one or more programs to:
recommend the customer to drive the vehicle when the number of cases in which the state of charge of the battery is less than or equal to a preset standard and the driving time of the vehicle is less than or equal to a preset standard driving time is higher than or equal to a preset number of times; and
notify the customer that the vehicle is normal when the number of cases in which the state of charge of the battery is less than or equal to a preset standard and the driving time of the vehicle is less than or equal to a preset standard driving time is less than a preset number of times.

10. The system according to claim 7, wherein when the processor executes the one or more programs to enter the battery care mode, the processor is configured to execute the one or more programs to:
enter a preset dark current minimization mode to ensure startability of the vehicle; and
notify the customer of problems caused by a functional limitation, and release and measures thereof.

11. A method for monitoring power of a vehicle, the method being performed on a computing device including a processor, and a storage medium in which one or more programs configured to be executable by the processor is recorded, the method comprising:
storing power consumption data for each preset vehicle state;
calculating an expected discharge time of a battery of the vehicle by calculating power consumption data classified by preset electrical equipment from data stored in the storing step, or confirming lack of a charge rate and charge time of a battery of the vehicle based on the stored power consumption data in the storing step and calculating a driving pattern of a customer; and
displaying the power consumption data of the electrical equipment and the expected discharge time of the battery calculated in the calculating step, or guiding a battery management plan based on the driving pattern of the customer calculated in the calculating step and suggesting entering a battery care mode for the battery.

12. The method according to claim 11, wherein storing the power consumption data includes:
controlling the power consumption data acquired by a battery sensor of the vehicle to be classified and stored based on the vehicle state.

13. The method according to claim 11, wherein calculating the expected discharge time of the battery includes:
classifying the stored power consumption data for each preset vehicle state based on preset types;
calculating power consumption data of the electrical equipment based on the classified power consumption data; and
calculating the expected discharge time of the battery based on a current charge rate of a battery.

14. The method according to claim 13, wherein calculating the power consumption data of the electrical equipment includes:
determining whether abnormal dark current is generated by the electrical equipment;
calculating the abnormal dark current based on consumption ampere-hours (ampere per hour, Ah) of an abnormal dark current higher than or equal to a preset reference value and consumption time of the abnormal dark current;
determining whether the calculated abnormal dark current is higher than or equal to a preset appropriate level;
calculating final abnormal dark current based on a difference between the abnormal dark current and a normal dark current of the vehicle; and
outputting a value of the calculated final abnormal dark current or an absence of the final abnormal dark current, and
wherein calculating the expected discharge time of the battery includes:
receiving a state of charge (SOC) of the battery;
calculating the expected discharge time of the battery based on a current SOC of the battery, a preset lower limit charge state for starting the vehicle, capacitance of the battery, and the final abnormal dark current; and
outputting the calculated expected discharge time.

15. The method according to claim 13, wherein displaying the power consumption data of the electrical equipment and the expected discharge time of the battery includes:
collecting a charge rate of the battery of the vehicle;
displaying the power consumption data of the electrical equipment based on the calculated power consumption data; and
displaying the expected discharge time of the battery by the electrical equipment.

16. The method according to claim 11, wherein the storing step includes:
classifying and storing power consumption data acquired by a battery sensor of the vehicle based on the vehicle state; and
entering the battery care mode according to the suggesting step.

17. The method according to claim 16, wherein the calculating step includes:
classifying the stored power consumption data for each vehicle state based on preset types;
confirming lack of a charge rate and charge time of the battery based on the classified power consumption data;
calculating an average driving pattern of the customer for a preset period of time;
sensing continuous pattern of lack of driving of the vehicle; and
recognizing a charge rate normal mode entry for the battery.

18. The method according to claim 17, wherein the suggesting step includes:
collecting a charge rate of the battery of the vehicle;
notifying a low-charge warning based on confirmation of the lack of the charge rate and charge time of the battery;
guiding a customer status and a battery management plan based on the calculated average driving pattern;
suggesting entering the battery care mode; and
releasing the battery care mode when the charge rate of the battery enters a normal mode,
wherein the step of calculating the driving pattern includes:
receiving charge state data of the battery for the period of time;
receiving driving data of the vehicle for the period of time; and
determining whether for the period of time, the number of cases in which the state of charge of the battery is less than or equal to a preset standard and driving time of the vehicle is less than or equal to a preset standard driving time is higher than or equal to a preset number of times, and
wherein the guiding step includes:
recommending the customer to drive the vehicle when the number of cases in which the state of charge of the battery is less than or equal to a preset standard and the driving time of the vehicle is less than or equal to a preset standard driving time is higher than or equal to a preset number of times; and
notifying the customer that the vehicle is normal when the number of cases in which the state of charge of the battery is less than or equal to a preset standard and the driving time of the vehicle is less than or equal to a preset standard driving time is less than a preset number of times.

19. The method according to claim 16, wherein the step of entering the battery care mode includes:
entering a preset dark current minimization mode to ensure startability of the vehicle; and
notifying the customer of problems caused by a functional limitation, and release and measures thereof.
